(19) United States
(12) Patent Application Publication
(10) Pub. No.: US 2021/0378144 A1
(43) Pub. Date: Dec. 2, 2021

(54) RADIATOR

(71) Applicant: KANTATSU CO., LTD., Tokyo (JP)

(72) Inventor: Eiji OSHIMA, Tokyo (JP)

(21) Appl. No.: 17/105,711

(22) Filed: Nov. 27, 2020

(30) Foreign Application Priority Data
Nov. 28, 2019 (JP) 2019-214898
Mar. 13, 2020 (JP) 2020-044550

(51) Int. Cl. H05K 7/20

(52) U.S. Cl. CPC H05K 7/20418; H01L 23/3672

(57) ABSTRACT

A radiator is provided having high heat dissipation performance while being compact and lightweight. A radiator 1 is configured from a base portion 4 having a heat receiving surface 2 abutting on a heat generating element, such as a semiconductor device and an electronic component, and a heat transfer surface 3 opposed to the heat receiving surface 2 and a fin 5 extending from the heat transfer surface 3 of the base portion 4. In the radiator 1 thus configured, the fin 5 is configured from a fin base 5a extending from the heat transfer surface 3 and a plurality of heat diffusing projections 8 and 9 formed on a surface of the fin base 5a.

### BACKGROUND OF THE INVENTION

### 1. Field of the Invention

The present invention relates to a radiator that diffuses heat released from a heat generating element, such as a semiconductor device and an electronic component, in the ambient air by abutting on the heat generating element.

### 2. Description of the Related Art

With an increase in performance and combination of functions in electronic equipment, industrial equipment, automobiles, and the like, semiconductor devices and electronic components with high current density, such as semiconductor integrated circuits, LED devices, and power semiconductors, are mounted on such equipment and automobiles. Since the semiconductor devices and the electronic components generate heat, it is important to prevent deterioration of components and reduction in performance due to the temperature rise. The temperature of such a device or component as a heat source is generally lowered by attaching a radiator, such as a heatsink, to the device or the component to dissipate the heat into the ambient air via the radiator. Such a radiator is generally produced from a highly thermally conductive metal material, such as copper alloy and aluminum alloy.

In recent years, semiconductor devices are increasingly integrated and densified and thus tend to cause an increase in the amount of heat generated from such a semiconductor device and an electronic component. It is possible to cope with the increase in the amount of heat generation by improving heat dissipation performance of a radiator. For example, attachment of a cooling fan to a radiator improves heat dissipation capability of the radiator due to the forced circulation of air by the cooling fan. However, electronic equipment and the like are even more miniaturized and densified and thus semiconductor devices and electronic components as heat generating elements have a space allowing implementation of a radiator while sometimes not allowing implementation of a cooling fan.

The radiator described in JP 2010-251730 A is configured from a base formed in a substantially vertical direction and a plurality of fins provided upright on one surface of the base. The fins are formed with plate members and provided with a thermal convection space formed between the fins having a width wider on the distal end side of the fins than on the base side, that is, to be radially upright on one surface of the base.

### SUMMARY

The radiator described in JP 2010-251730 A allows natural air cooling with high cooling power to a heat generating element, such as a semiconductor device and an electronic component, even in a narrow space where it is difficult to implement a cooling fan. However, the amount of heat generated from such a semiconductor device and an electronic component increases year by year with the miniaturization and densification of electronic equipment and the like, and the radiator described in JP 2010-251730 A itself has to increase in size in accordance with the amount of heat from the heat generating element in order to diffuse the heat from the heat generating element in the ambient air. The radiator described in JP 2010-251730 A naturally has a limitation on the heat dissipation capability.

The present invention has been made in view of such a problem and it is an object thereof to provide a radiator with high heat dissipation performance while being compact and lightweight.

To achieve the above object, a radiator of the present invention includes: a base portion having a heat receiving surface in contact with a heat generating element and a heat transfer surface opposed to the heat receiving surface; and a fin extending from the heat transfer surface. The fin has one or a plurality of fin bases extending from the heat transfer surface and one or a plurality of heat diffusing projections formed on a surface of each fin base.

The radiator, for example a heatsink, is generally produced by a production technique, such as extrusion, cutting, skiving, cold forging, die casting, and stamping, using a highly thermally conductive material, such as copper alloy and aluminum alloy. The shape of fins to dissipate the heat in the air is often in a substantially plate shape due to process constraints.

In the past, such an increase in the amount of heat from the heat generating element, such as a semiconductor device and an electronic component, used to be addressed by increasing the number of fins. However, since the radiator thus configured increases in size with the increase in the amount of heat from the heat generating element, it is difficult to cope with miniaturization and densification of the electronic equipment and the like.

In the radiator of the present invention, the fin is configured from the one or plurality of fin bases extending from the heat transfer surface of the base portion and the one or plurality of heat diffusing projections formed on the surface of each fin base. The heat released from the heat generating element is transmitted to the heat receiving surface of the base portion and then to each fin base and to each heat diffusing projection. The heat transmitted to the fin dissipated from each fin base and each heat diffusing projection. Each heat diffusing projection provided on the surface of each fin base causes an increase in heat dissipation area of the fin and it is thus possible to improve the heat dissipation performance of the radiator without increasing the size of the fin. In addition, since the increase in the size of the fin is thus suppressed, it is possible to preferably suppress the increase in the size of the radiator with an increase in the amount of heat from the heat generating element and to achieve weight reduction of the radiator.

In the radiator, it is desired that the base portion, each fin base, and each heat diffusing projection are integrally formed as a single piece. This allows reduction in the number of components configuring the radiator and achievement of miniaturization and even more weight reduction of the radiator. The processing method to integrally form a complex shape as a single piece includes a processing method in which a photocurable resin is irradiated with light, such as a laser, for shaping, the method being so-called stereolithography.

In the radiator, it is desired that the base portion and the fin are formed from a synthetic resin.

In recent years, highly thermally conductive synthetic resins are developed. Formation of the radiator from a synthetic resin facilitates formation of each heat diffusing projection on the surface of each fin base and also allows formation of the heat diffusing projection with a complex shape. This allows an even more increase in the heat dissipation area of the fin by increasing the surface area of the heat diffusing projection. In addition, a synthetic resin material is generally lightweight compared with a metal material and thus allows achievement of weight reduction of the radiator in a preferred manner. An example of the processing method to form the radiator from such a synthetic resin includes the stereolithography described above.

In the radiator, it is desired that each fin base is formed in a plate shape and has one bottom surface formed integrally with the heat transfer surface as a single piece, and each fin base has a side surface provided with the plurality of heat diffusing projections.

In the fin, a surface to provide each heat diffusing projection may be any surface other than the bottom surface integrally formed with the heat transfer surface of the base portion as a single piece. Considering miniaturization of the electronic equipment and the like, the length of the direction of extension of the fin is often limited. The heat diffusing projection provided on a side surface of the fin base allows miniaturization of the electronic equipment and the like in a preferred manner.

The fin base is considered to have various shapes, such as a square column, a cylindrical column, and a spindle shape while the fin base desirably has the side surface with a wider surface area to be provided with the plurality of heat diffusing projections. An example of such a shape is considered to include a substantially plate shape.

In the radiator, the heat diffusing projections are desirably provided on at least one surface of a side surface with a wider surface area among the side surfaces of the fin base. The heat diffusing projections provided on the side surface with a wider surface area among the side surfaces of the fin base allow an efficient increase in the heat dissipation area of the fin. It should be noted that, for an even more increase in the heat dissipation area of the fin, the heat diffusing projections are desirably provided two side surfaces with a wider surface area among the side surfaces of the fin.

In a natural air-cooling radiator, thermal convection occurs in a space between the fins and the thermal convection diffuse the heat of the fins in the ambient air. In the above radiator, it is thus desired that the plurality of fins extend and the fins adjacent to each other have the respective fin bases provided with the plurality of heat diffusing projections on the opposed side surfaces. The plurality of a heat diffusing projections are thus provided in the thermal convection space between the fins to allow efficient thermal diffusion in the ambient air by increasing the heat dissipation area.

It should be noted that the array of the heat diffusing projections relative to the side surface of each fin base is desirably changed depending on the mode of installing the radiator to the heat generating element. As described above, in the natural air-cooling radiator, the heat is diffused in the ambient air by thermal convection between the fins. For example, when the heat transfer surface of the base portion is close to horizontal, the heat transfers from the basal portion of the fin to the distal end portion. Accordingly, the heat diffusing projections are desirably provided not to inhibit the air flow along the direction of extension of the fin.

Meanwhile, when the heat transfer surface of the base portion is close to vertical, the heat transfers across the fin and thus the heat diffusing projections are desirably provided not to inhibit the air flow along the direction orthogonal to the direction of extension of the fin. The heat diffusing projections thus arranged in accordance with the mode of installing the radiator allows smooth heat transfer and consequently efficient thermal diffusion in the ambient air.

The heat diffusing projections provided on the surface of the fin base causes an increase in the thickness of the fin only in that area. The difference in thickness of the fin between the areas provided with the projections and provided with no projections may cause concentration of heat locally inside the fin. In the above radiator, each heat diffusing projection is desirably formed periodically relative to the side surface of the fin base. The heat diffusing projections formed periodically, that is, the heat diffusing projections formed at substantially regular intervals allow suppression of the local heat concentration in the fin. It is thus possible to improve the heat dissipation performance of the radiator.

It is desired that the radiator further includes a plurality of the fins, wherein the heat diffusing projections are formed on the opposed side surfaces of the respective fin bases to be phase shifted 180° relative to each other.

When the plurality of fins extend on the base portion, the fins are in a state of being opposed to each other. The heat diffusing projections are provided on the opposed side surfaces of the respective fin bases to be phase shifted 180° relative to each other, thereby allowing the thickness of the thermal convection space formed between the fins to be substantially uniform. A heat transfer path is thus secured well, allowing more efficient thermal diffusion in the ambient air.

A radiator according to the present invention includes: a base portion having a heat receiving surface in contact with a heat generating element and a heat transfer surface opposed to the heat receiving surface; and a fin extending from the heat transfer surface, wherein a passage is formed inside either one or both of the base portion and the fin.

The heat released from the heat generating element is transmitted to the base portion. A working fluid flowing in the passage causes the heat transmitted to the base portion to be transferred outside the radiator. Addition of the heat transfer by the working fluid to the thermal diffusion from the fin into the ambient air allows more efficient dissipation of the heat from the heat generating element. It should be noted that the working fluid generally refers to a liquid or a gas and also includes a mixture of liquid and gas and a special fluid, such as a multiphase fluid in which a small amount of solid is mixed in a liquid, a gas, or a mixture thereof.

In the radiator, it is desired that the passage is disposed in a position close to the heat receiving surface inside the base portion and disposed in a corrugated manner in a direction orthogonal to a direction of extension of the fin inside the fin.

When the working fluid flows in the passage, the heat dissipated from the heat generating element is transmitted to the working fluid in the passage via the heat receiving surface of the base portion. The heat in the working fluid is then transmitted to the fin by the working fluid flowing in the passage provided inside the fin. The passage inside the fin is corrugated in the direction orthogonal to the direction of extension of the fin. The heat in the working fluid is thus transmitted uniformly inside the fin and efficiently diffused in the ambient air through the heat diffusing projections of the fin. It is accordingly possible to even more efficiently diffuse the heat from the fin into the ambient air and transfer the heat by the working fluid.

In the radiator, it is desired that the passage has a plated coating on an inner surface thereof. An example of plating capable of forming a plated coating on a material other than conductors includes electroless plating. Electroless plating is a method of forming a uniform plated coating by immersing a material in a plating solution. Electroless plating allows formation of a plated coating not only metal materials but also synthetic resin materials. The bath type is desirably highly thermally conductive. Examples of the type include electroless gold plating, electroless silver plating, electroless copper plating, and the like. In the radiator of the present invention, electroless plating, for example electroless copper plating, applied to the inner surface of the passage allows improvement of the heat dissipation performance of the radiator. It should be noted that the thickness of plating is desirably determined in accordance with the heat dissipation performance of the radiator because the thickness of the plated coating is controlled by plating conditions, such as the temperature of the plating solution and the immersion time.

In the radiator, it is desired that a plated coating is formed on the entire surface thereof. For example, the entire radiator subjected to electroless plating allows even more improvement of the heat dissipation performance of the radiator without increasing the size of the radiator. It should be noted that the plated coating is not limited to the coating by electroless plating and the plating method is not limited as long as the plated coating is highly thermally conductive.

The radiator of the present invention causes an increase in the surface area of the fin due to the heat diffusing projection formed on the fin and improves the thermal diffusion performance of the fin, and thus provides a radiator with high heat dissipation performance while being compact and lightweight.

### BRIEF DESCRIPTION OF THE DRAWINGS

FIG. 1 is a perspective view schematically illustrating an appearance of a radiator according to a first embodiment of the present invention.

FIG. 2 is a plan view of the radiator illustrated in FIG. 1.

FIG. 3 is an A-A cross-sectional view of the radiator illustrated in FIG. 2.

FIG. 4 is a perspective view schematically illustrating a passage provided inside the radiator illustrated in FIG. 1.

FIG. 5 is a perspective view schematically illustrating an appearance of a radiator according to a second embodiment of the present invention.

FIG. 6 is a plan view of the radiator illustrated in FIG. 5.

FIG. 7 is a B-B cross-sectional view of the radiator illustrated in FIG. 6.

FIG. 8 is a perspective view schematically illustrating a passage provided inside the radiator illustrated in FIG. 5.

FIG. 9 is a plan view of the passage illustrated in FIG. 8.

FIG. 10 is a cross-sectional view of an embodiment of a plated coating in FIG. 3.

### DETAILED DESCRIPTION OF THE PREFERRED EMBODIMENTS

### First Embodiment

The first embodiment of the present invention is described below in detail with reference to the drawings.

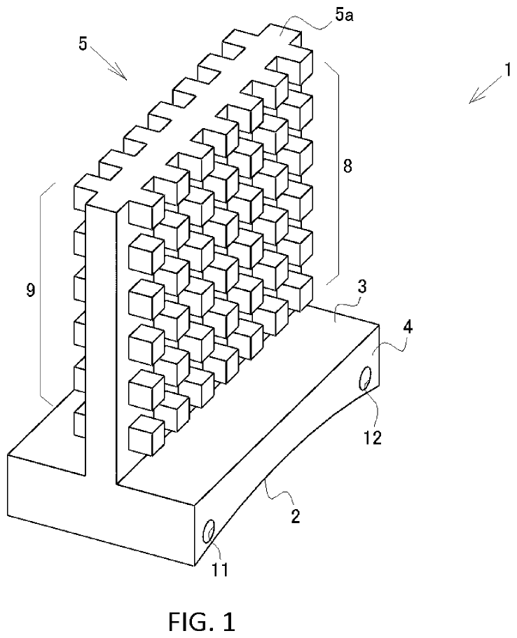

A radiator according to the present embodiment abuts on a heat generating element, such as a semiconductor device and an electronic component, to diffuse the heat generated by the heat generating element in the ambient air. As illustrated in FIG. 1, a radiator 1 has a substantially convex shape as a whole and includes: a base portion 4 having a heat receiving surface 2 in contact with the heat generating element and a heat transfer surface 3 opposed to the heat receiving surface 2; and a fin 5 extending from the heat transfer surface 3 of the base portion 4.

In the present embodiment, the heat generating element is assumed to have a curved shape and the heat receiving surface 2 of the base portion 4 is formed in a shape matching the curved shape of the heat generating element. The radiator 1 thus closely contacts with the heat generating element. The heat receiving surface 2 thus formed in the shape matching the shape of the heat generating element in contact with the heat receiving surface 2 allows efficient transmission of the heat from the heat generating element to the base portion 4. It should be noted that the shape of the heat receiving surface 2 is not limited to such a curved surface. The shape may be flat as a general radiator in the past. As the shape of the heat receiving surface 2, an arbitrary shape may be selected in accordance with the shape of the heat generating element. For example, when a plurality of heat generating elements are implemented to a circuit board or the like, the heat receiving surface 2 may be formed in a shape matching the shape of the heat generating elements. The radiator 1 in close contact with the heat generating elements is capable of diffusing the heat from the heat generating elements in the ambient air.

The fin 5 has: a fin base 5a integrally formed with the heat transfer surface 3 of the base portion 4 as a single piece; and a plurality of heat diffusing projections formed on a surface of the fin base 5a. The heat diffusing projections are described later in detail.

The fin base 5a is formed in a plate shape and has one bottom surface integrally formed with the heat transfer surface 3 of the base portion 4 as a single piece. Specifically, the fin base 5a is formed in a shape with a rectangular transverse cross section. The shape of the fin base 5a is not limited to the shape according to the present embodiment and may be in a shape with a transverse cross section of, for example, a square, trapezoidal, triangular, circular, elliptical, or spindle shape. The “transverse cross section” is defined herein as a flat surface vertical to the direction of extension of the fin 5.

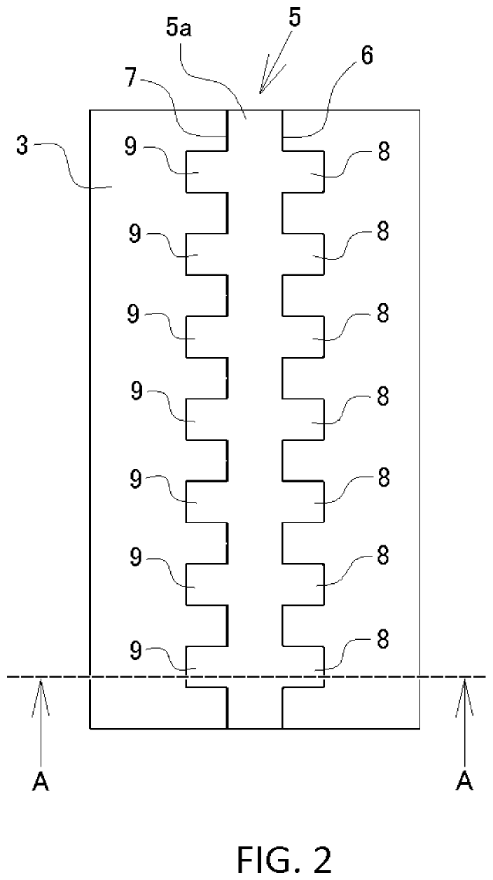

As illustrated in FIGS. 1 and 2, the fin base 5a has both side surfaces 6 and 7 provided respectively with a plurality of heat diffusing projections 8 and 9 in a substantially cubic shape. The side surfaces 6 and 7 here are side surfaces corresponding to the longitudinal sides of the transverse cross section of the fin base 5a and equivalent to the two side surfaces with a wider surface area among the side surfaces of the fin base 5a.

The heat diffusing projections 8 and 9 are periodically formed on the respective side surfaces 6 and 7. That is, the heat diffusing projections 8 and 9 are arranged in a grid at regular intervals on the respective side surfaces 6 and 7. In the present embodiment, the side surfaces 6 and 7 are provided with a total of 42 heat diffusing projections 8 and 9 in seven columns along the direction of extension of the fin 5 and six rows along a direction orthogonal to the direction of extension. The heat diffusing projections 8 and 9 periodically formed relative to the side surfaces 6 and 7 allow suppression of local heat concentration in the fin 5. In addition, the plurality of heat diffusing projections 8 and 9 provided on both side surfaces 6 and 7 of the fin base 5a increase the heat dissipation area of the fin 5 and thus allow improvement of the heat dissipation performance of the radiator 1.

It should be noted that the shape of the heat diffusing projections 8 and 9 is not limited to the substantially cubic shape. For example, a three dimensional shape, such as a rectangular parallelepiped, a triangular column, a quadrangular pyramid, a triangular pyramid, a circular cone, a cylindrical column, and a hemisphere, may be employed as the shape of the heat diffusing projections 8 and 9. In addition to the grid array described above, the arrays of the heat diffusing projections 8 and 9 may be, for example, a random arrangement where the phase is shifted from each other.

The material to form the radiator 1 is then described. As described above, the radiator 1 has a complex shape. Accordingly, the radiator 1 uses a highly thermally conductive photocurable synthetic resin as the material. The processing method to be used is a processing method in which the photocurable resin is irradiated with light, such as a laser, for shaping, the method being so-called stereolithography. The process by stereolithography allows formation of the complex shape in a short time. The synthetic resin desirably has a thermal conductivity of 1 W/mK or more. The synthetic resin more preferably has a thermal conductivity from 2 to 5 W/mK. Use of the highly thermally conductive synthetic resin as the material allows formation of the radiator 1 with high thermal diffusion performance while being lightweight.

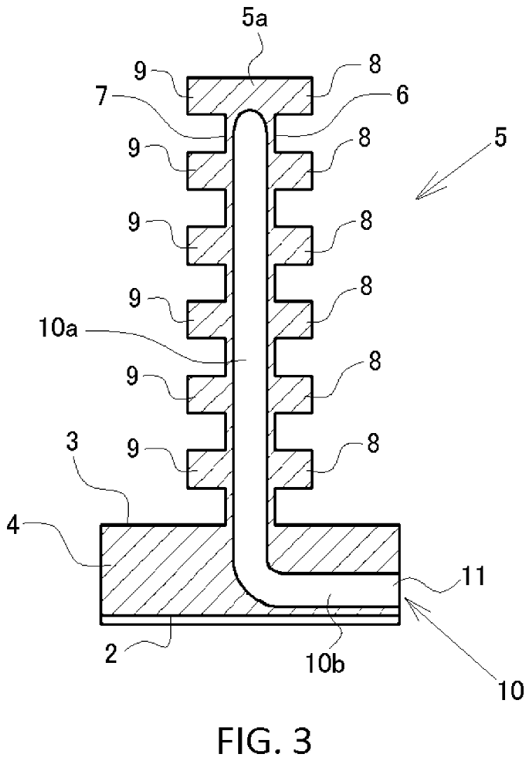

As illustrated in FIG. 3, a passage 10 is formed inside the base portion 4 and the fin 5. In the present embodiment, the passage 10 is formed in a hollow tubular shape with a circular transverse cross section. The passage 10 is configured from a corrugated tube portion 10a disposed inside the fin 5 and tube connection portions 10b disposed inside the base portion 4. The tube connection portions 10b are disposed in positions close to the heat receiving surface 2 inside the base portion 4. The passage 10 has ends connected to a side surface of the base portion 4.

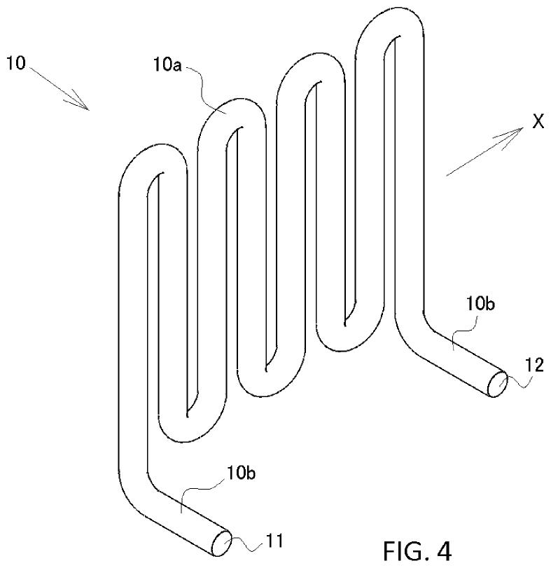

FIG. 4 is a perspective view schematically illustrating only the passage 10 formed inside the radiator 1. As illustrated in FIG. 4, the corrugated tube portion 10a is disposed in a corrugated manner in a direction X orthogonal to the direction of extension of the fin 5. Although the number of turns of the corrugated tube portion 10a is not limited, the number is desirably same as or close to the number of the columns of the heat diffusing projections. The ends of the passage 10 are respectively a passage inlet 11 and a passage outlet 12 and respectively connected to the side surface of the base portion 4.

The working fluid flowing from the passage inlet 11 into the passage 10 firstly reaches one of the tube connection portion 10b. Since the tube connection portion 10b is disposed in the position close to the heat receiving surface 2, the heat released from the heat generating element is transmitted to the working fluid in the tube connection portion 10b via the heat receiving surface 2 of the base portion 4. The working fluid in the tube connection portion 10b then flows in the corrugated tube portion 10a. The corrugated tube portion 10a is disposed in a state of being corrugated in the fin 5, having the side surfaces provided with the heat diffusing projections 8 and 9. The heat of the working fluid is thus partially diffused in the ambient air through the heat diffusing projections 8 and 9.

The working fluid in the corrugated tube portion 10a then reaches the other tube connection portion 10b and flows out of the passage outlet 12. The outflow of the working fluid from the passage outlet 12 transfers part of the heat released from the heat generating element outside the radiator 1. Accordingly, the radiator 1 according to the present embodiment is capable of more efficient dissipation of the heat from the heat generating element because heat transfer by the working fluid is added to the thermal diffusion from the fin 5 into the ambient air. It should be noted that, although the working fluid is considered to be water or a liquid coolant, the fluid may be a gas, such as vaporized metal. The fluid may also be a mixture of liquid and gas and a special fluid, such as a multiphase fluid in which a small amount of solid is mixed in a liquid, a gas, or a mixture thereof.

### Second Embodiment

The second embodiment of the present invention is then described below in detail with reference to the drawings. A radiator according to the present embodiment includes a plurality of fins.

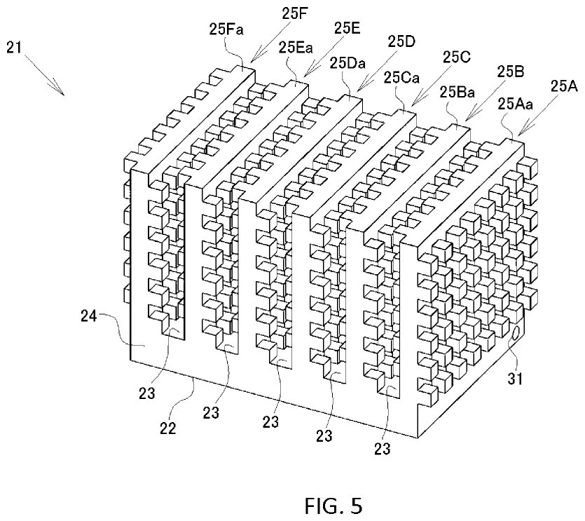

As illustrated in FIG. 5, a radiator 21 has a substantially rectangular parallelepiped shape as a whole and includes: a base portion 24 in a plate shape having a heat receiving surface 22 in contact with a heat generating element, such as a semiconductor device and an electronic component, and a heat transfer surface 23 opposed to the heat receiving surface 22; and a plurality of fins 25A, 25B, 25C, 25D, 25E, and 25F extending from the heat transfer surface 23 of the base portion 24. The fins 25A through 25F respectively have: fin bases 25Aa, 25Ba, 25Ca, 25Da, 25Ea, and 25Fa integrally formed with the heat transfer surface 23 of the base portion 24 as a single piece; and a plurality of heat diffusing projections formed on surfaces of the fin bases 25Aa through 25Fa.

Each of the fin bases 25Aa through 25Fa is formed in a plate shape and has one bottom surface integrally formed with the heat transfer surface 23 of the base portion 24 as a single piece. The fin bases 25Aa through 25Fa are formed in a shape with a rectangular cross section and provided upright in parallel at regular intervals to have side surfaces opposed to each other, which are longitudinal sides of each transverse cross section. The shape and the arrangement of the fin bases 25Aa through 25Fa are not limited to those according to the present embodiment, same as the first embodiment.

In the present embodiment, the fins 25A through 25F have an identical shape. For the convenience of the description, a detailed description is given below only to the shape of the fin 25A to omit a description on the shape of the other fins 25B through 25F.

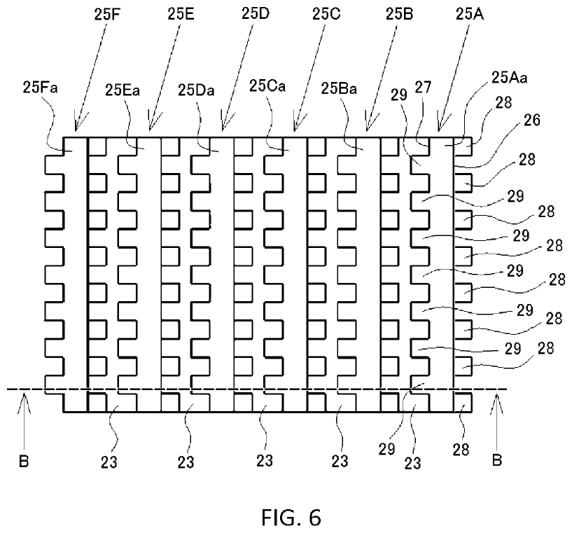

As illustrated in FIG. 6, the fin base 25Aa has both side surfaces 26 and 27 provided respectively with a plurality of heat diffusing projections 28 and 29 having a substantially cubic shape. The side surfaces 26 and 27 here are side surfaces corresponding to the longitudinal sides of the transverse cross section of the fin base 25Aa and equivalent to the two side surfaces with a wider surface area among the side surfaces of the fin base 25Aa.

The heat diffusing projections 28 and 29 are periodically formed relative to the side surfaces 26 and 27. In the present embodiment, the side surface 26 is provided with a total of 48 heat diffusing projections 28 in eight columns along the direction of extension of the fin 25A and six rows along a direction orthogonal to the direction of extension. Meanwhile, the side surface 27 is provided with a total of 42 heat diffusing projections 29 in seven columns along the direction of extension of the fin 25A and six rows along a direction orthogonal to the direction of extension. The heat diffusing projections 28 and 29 are arranged alternately across the fin base 25Aa to be phase shifted 180° relative to each other. The heat diffusing projections 28 and 29 thus arranged prevents large variation in the thickness in the short side direction of the transverse cross section of the fin base 25Aa and thus allows suppression of local heat concentration in the fin 25A.

In the radiator, the heat is diffused in the ambient air by thermal convection between the fins. When the heat transfer surface of the base portion is close to horizontal, the heat transfers from the basal portion of the fin to the distal end portion. Meanwhile, when the heat transfer surface of the base portion is close to vertical, the heat transfers across the fin. The optimal array of the heat diffusing projections has to be determined in accordance with the mode of installing the radiator to the heat generating element. In this respect, the radiator 21 according to the present embodiment has the periodic arrays of the heat diffusing projections 28 and 29 and thus allows good thermal diffusion regardless of the mode of installing the radiator 21.

It should be noted that, as the shape and the arrays of the heat diffusing projections 28 and 29, various types of them may be employed same as the first embodiment.

A description is then given to the relationship between the heat diffusing projections in the fins adjacent to each other taking the fins 25A and 25B as an example. In this description, the heat diffusing projections provided on the side surface on the fin 25A side in the fin 25B are referred using the reference sign “28” for convenience.

The heat diffusing projections 29 provided on the side surface 27 of the fin 25A and the heat diffusing projections “28” provided on the side surface of the fin 25B opposed to the side surface 27 are phase shifted 180° relative to each other. That is, the heat diffusing projections 29 and “28” are formed to be phase shifted 180° relative to each other on the respective side surfaces of the fin bases 25Aa and 25Ba, and thus the heat diffusing projections “28” are not provided in the positions facing the heat diffusing projections 29. Due to such arrays of the heat diffusing projections 29 and “28”, an appropriate gap is secured between the heat diffusing projections 29 and “28”. In the process of heat dissipation from the fins 25A and 25B, thermal convection occurs in the gap formed between the fins 25A and 25B. In this situation, the presence of the gap allows smooth thermal convection and therefore allows efficient thermal diffusion from the fins 25A through 25F.

Accordingly, the radiator 21 according to the present embodiment also increases the heat dissipation areas of the fins 25A through 25F by the plurality of heat diffusing projections provided on both side surfaces of the fin bases 25Aa through 25Fa and thus allows improvement of the heat dissipation performance of the radiator 21.

The radiator 21 according to the present embodiment uses a highly thermally conductive photocurable synthetic resin as the material, same as the first embodiment. The processing method to be used is stereolithography described above. It should be noted that the synthetic resin to form the radiator 21 according to the present embodiment also desirably has a thermal conductivity of 1 W/mK or more and more preferably from 2 to 5 W/mK.

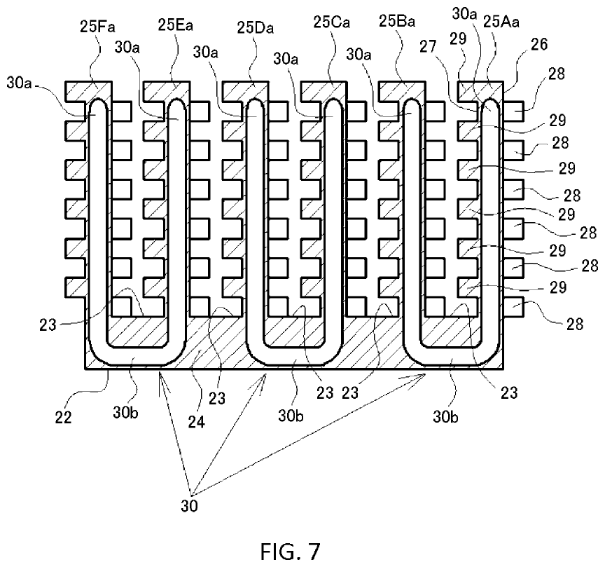

As illustrated in FIG. 7, a passage 30 is formed inside the base portion 24 and the fins 25A through 25F. In the present embodiment, the passage 30 is formed in a hollow tubular shape with a circular transverse cross section. The passage 30 is configured from corrugated tube portions 30a disposed inside the fin bases 25Aa through 25Fa and tube connection portions 30b disposed inside the base portion 24. The tube connection portions 30b are disposed in positions close to the heat receiving surface 22 inside the base portion 24.

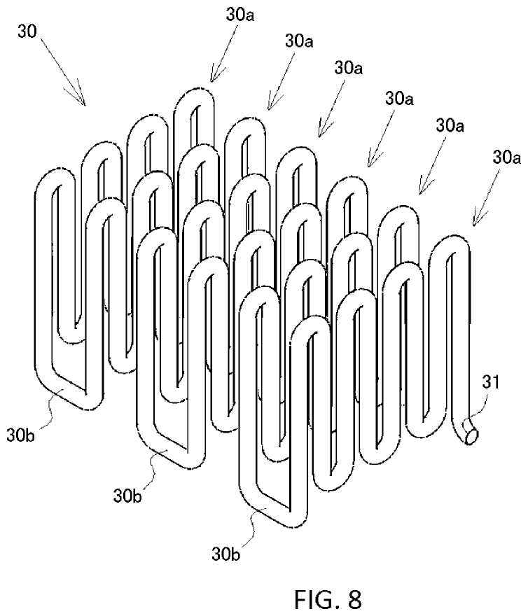

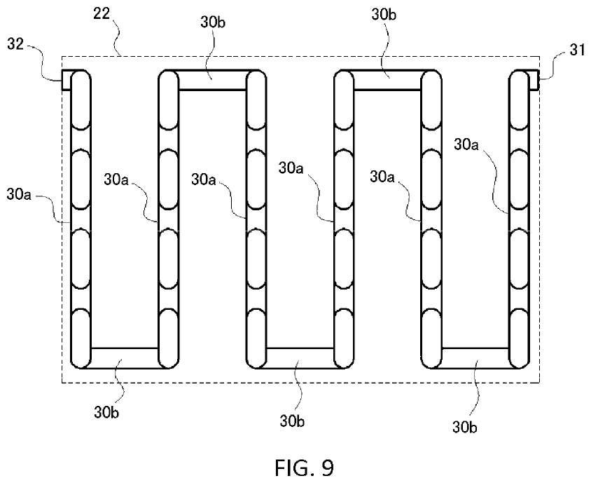

FIG. 8 is a perspective view schematically illustrating only the passage 30 formed inside the radiator 21. FIG. 9 is a plan view of the passage 30. As illustrated in FIGS. 8 and 9, the corrugated tube portions 30a are disposed in a corrugated manner in a direction orthogonal to the direction of extension of the fins 25A through 25F. Although the number of turns of the corrugated tube portions 30a is not limited, the number is desirably same as or close to the number of the columns of the heat diffusing projections. The corrugated tube portions 30a are respectively coupled to the tube connection portions 30b. The ends of the passage 30 are respectively a passage inlet 31 and a passage outlet 32. In the radiator 21 according to the present embodiment, the passage inlet 31 is connected to a side surface of the base portion 24 and the passage outlet 32 is connected to a side surface on the opposite side of the base portion 24, which is opposed to the former side surface.

When a working fluid flows from the passage inlet 31 into the passage 30, the working fluid flows through one of the corrugated tube portions 30a and reaches one of the tube connection portions 30b. Since the tube connection portion 30b is disposed in the position close to the heat receiving surface 22, the heat released from the heat generating element is transmitted to the working fluid in the tube connection portion 30b via the heat receiving surface 22 of the base portion 24. The working fluid in the tube connection portion 30b then flows in one corrugated tube portion 30a in the fin 25B. In this situation, the heat of the working fluid is partially diffused in the ambient air through the heat diffusing projections provided on the surface of the fin 25B.

The working fluid in the corrugated tube portion 30a then reaches another tube connection portion 30b and receives the heat released from the heat generating element again via the heat receiving surface 22 of the base portion 24. The working fluid then flows in one corrugated tube portion 30a in the fin 25C. The working fluid thus flows sequentially in the tube connection portion 30b, the corrugated tube portion 30a, the tube connection portion 30b, the corrugated tube portion 30a, . . . to efficiently exchange the heat released from the heat generating element. In addition, the outflow of the working fluid from the passage outlet 32 transfers part of the heat released from the heat generating element outside the radiator 21. Accordingly, the radiator 21 according to the present embodiment is capable of more efficient dissipation of the heat from the heat generating element because heat transfer by the working fluid is added to the thermal diffusion from the fins 25A through 25F into the ambient air. It should be noted that, although the working fluid is considered to be: water; a liquid coolant; a gas, such as vaporized metal; vaporized metal; a multiphase fluid; or the like, same as the first embodiment.

As described above, the radiator according to each embodiment above allows efficient cooling of a heat generating element while being compact and lightweight.

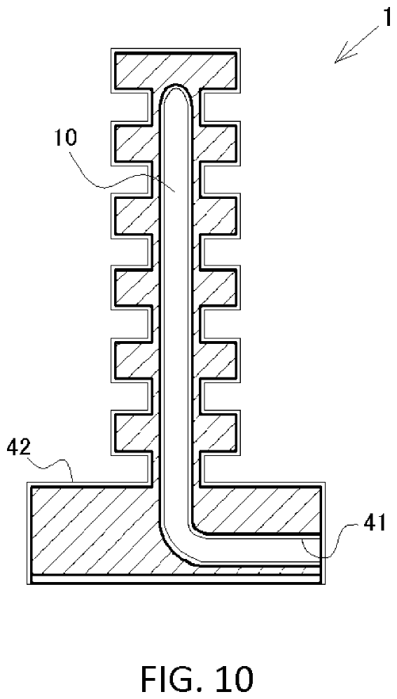

In the radiator according to each embodiment above, the passage is formed in a hollow tubular shape with a circular transverse cross section. To further improve the heat dissipation performance of the radiator, electroless plating (e.g., electroless copper plating) may be applied to the inner surface of the passage. The radiator is immersed in a plating solution bath to form a plated coating in the passage. As illustrated in FIG. 10 for example, a plated coating 41 is thus formed on the inner surface of the passage 10. The thickness of the plated coating 41 may be controlled by plating conditions, such as the temperature of the plating solution and the immersion time.

Similarly, the entire radiator may be subjected to electroless plating. As illustrated in FIG. 10, a plated coating 42 is formed on the entire surface of the radiator 1, thereby allowing even more improvement of the heat dissipation performance of the radiator 1 without increasing the size of the radiator 1.

In the radiator according to each embodiment above, the base portion and the fin(s) are integrally formed as a single piece. However, the base portion and the fin(s) may be separately formed, without integrally forming them as a single piece, and joined with an adhesive or the like. Although the radiator is formed using the highly thermally conductive synthetic resin in each embodiment above, the radiator may be formed using highly thermally conductive metal. In recent years, processing methods are also widespread, such as a shaping method in which metal powder is laminated while sintering to form a three dimensional shape, so-called selective laser sintering. Use of such a processing method allows formation of the radiator according to the present embodiment from the metal material.

In the radiator according to each embodiment above, the number of fins may be appropriately increased or decreased in accordance with the amount of heat from the heat generating element. In addition, the number of heat diffusing projections is not limited to the number according to each embodiment above.

Although the passage in the radiator according to each embodiment above is one corrugated passage, a plurality of passages may be provided inside the radiator. While one passage causes limitation in the mode of disposing inside the radiator depending on the number of the fins, an increase in the fins, such as two or three, causes a greater degree of freedom in the disposing mode. The plurality of passages provided inside the radiator allows fine heat dissipation by, for example, abutting the single radiator on a plurality of heat generating elements and differentiating the type, the flow velocity, and the like of working fluid flowing in the passages disposed in the position corresponding to each heat generating element in accordance with the amount of heat from each heat generating element.

In the radiator according to each embodiment above, the passage is formed inside of both the base portion and the fin(s). However, the passage may be formed inside of either one of the base portion and the fin(s). Even when the passage is formed only inside the base portion or only inside the fin(s) in such a manner, it is possible to improve the heat dissipation performance of the radiator by heat transfer by the working fluid flowing in the passage.

An application of the radiator according to the present invention is not limited to the application of diffusing the heat released from the heat generating element in the ambient air. The radiator according to the present invention increases the thermal diffusion area of the fin(s) more than the area of a radiator in the past. Accordingly, for example, the fins of the radiator are immersed in a container with a liquid at a high temperature and the liquid coolant is caused to flow in the passage, thereby allowing an efficient decrease in the temperature of the liquid in the container. On the contrary, the fins are immersed in a container with a liquid at a low temperature and a liquid at a high temperature is caused to flow in the passage, thereby allowing an efficient temperature rise of the liquid in the container. The radiator according to the present invention may be used as a heat exchanger in such a manner.

The summary of the invention to apply the radiator according to the present invention to the heat exchanger is described as follows:

a heat exchanger, including:

a base portion;

a fin extending from the base portion; and

one or a plurality of passages formed inside the base portion and the fin, wherein

the fin has a fin base extending from the base portion and one or a plurality of heat diffusing projections formed on a surface of the fin base, and

the passage is disposed in a corrugated manner in a direction orthogonal to a direction of extension of the fin inside the fin.

As has been described above, the radiator according to the present invention allows efficient diffusion of the heat in the ambient air, the heat released from semiconductor devices, electronic components, and the like mounted on electronic equipment, industrial machines, automobiles, and the like.

The present invention is applicable to a radiator to cool a heat generating element, such as a semiconductor device and an electronic component, mounted on electronic equipment, an industrial machine, an automobile, and the like.

1-9. (canceled)

10. A radiator, comprising:
a base portion having a heat receiving surface in contact with a heat generating element and a heat transfer surface opposed to the heat receiving surface; and
a fin extending from the heat transfer surface, wherein
the fin has one or a plurality of fin bases extending from the heat transfer surface and one or a plurality of heat diffusing projections formed on a surface of each fin base.

11. The radiator according to claim 10, wherein the base portion, each fin base, and each heat diffusing projection are integrally formed as a single piece.

12. The radiator according to claim 10, wherein the base portion and the fin are formed from a synthetic resin.

13. The radiator according to claim 10, wherein
each fin base is formed in a plate shape and has one bottom surface formed integrally with the heat transfer surface as a single piece, and
each fin base has a side surface provided with the plurality of heat diffusing projections.

14. The radiator according to claim 10, further comprising a plurality of the fins, wherein
the fins adjacent to each other have the respective fin bases provided with the heat diffusing projections on the opposed side surfaces, the projections being arranged to be phase shifted 180° relative to each other.

15. The radiator according to claim 14, wherein a plated coating is formed on a surface thereof.

16. A radiator, comprising:
a base portion having a heat receiving surface in contact with a heat generating element and a heat transfer surface opposed to the heat receiving surface; and
a fin extending from the heat transfer surface, wherein
a passage is formed inside either one or both of the base portion and the fin.

17. The radiator according to claim 16, wherein the passage is disposed in a position close to the heat receiving surface inside the base portion and disposed in a corrugated manner in a direction orthogonal to a direction of extension of the fin inside the fin.

18. The radiator according to claim 16, wherein the passage has a plated coating on an inner surface thereof.

19. The radiator according to claim 16, wherein a plated coating is formed on a surface thereof.
